(19) United States
(12) Patent Application Publication
(10) Pub. No.: US 2026/0282714 A1
(43) Pub. Date: Sep. 17, 2026

(54) DISPLAY PANEL AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventor: Rui LIU, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/995,906

(22) PCT Filed: Oct. 31, 2023
(86) PCT No.: PCT/CN2023/128491

§ 371 Date: Jan. 17, 2025

(30) Foreign Application Priority Data
Oct. 25, 2022 (CN) 202211313527.0

(51) Int. Cl. H10K 59/80; H10H 29/14; H10H 29/80; H10H 29/854

(52) U.S. Cl. CPC H10K 59/8731; H10H 29/142; H10H 29/8421; H10H 29/854; H10K 59/878

(57) ABSTRACT

The present disclosure relates to a display panel and a display device, and relates to the field of display technology. The display panel of the present disclosure comprises a driving backplane, a plurality of light emitting devices and an encapsulation layer. The light emitting devices are distributed in an array on a side of the driving backplane. The encapsulation layer covers the light emitting devices. The encapsulation layer comprises a first inorganic layer, a reflective layer and a second inorganic layer distributed in sequence in a direction away from the driving backplane. The reflective layer comprises a plurality of first light transmitting holes, and the first light transmitting holes overlap with at least one of the light emitting devices. The display panel of the present disclosure may improve color deviation while achieving mirror display.

### CROSS REFERENCE

The present disclosure is a U.S. national phase application based on PCT/CN2023/128491 filed on Oct. 31, 2023, which claims the benefit of Chinese application No. 202211313527.0 filed on Oct. 25, 2022 and entitled “DISPLAY PANEL AND DISPLAY DEVICE”, both of which is are incorporated herein by reference in their entireties.

### TECHNICAL FIELD

The present disclosure relates to the field of display technology, and in particular to a display panel and a display device.

### BACKGROUND

A display panel obtained by combining the display function with the mirror function may not only display images, but also be used as a mirror. The display panel with the mirror display function may be applied to the fields of vehicle rearview mirrors, home furnishings, advertising, etc. However, the existing display panels with the mirror display function are prone to color deviation, which affects the display effect.

It should be noted that the information disclosed in the above background technology section is only used to enhance the understanding of the background of the present disclosure, and therefore may include information that does not constitute the prior art known to ordinary technicians in the field.

### SUMMARY

An object of the present disclosure is to provide a display panel and a display device.

According to one aspect of the present disclosure, there is provided a display panel, comprising:
a driving backplane;
a plurality of light emitting devices, distributed in an array on a side of the driving backplane;
an encapsulation layer, covering the light emitting devices, wherein the encapsulation layer comprises a first inorganic layer, a reflective layer and a second inorganic layer distributed in sequence in a direction away from the driving backplane; the reflective layer comprises a plurality of first light transmitting holes, and the first light transmitting holes overlap with at least one of the light emitting devices.

In an exemplary embodiment of the present disclosure, the encapsulation layer further comprises:
a light absorbing layer, disposed between the first inorganic layer and the reflective layer, having a plurality of second light transmitting holes, and one of the second light transmitting holes overlaps with one of the first light transmitting holes.

In an exemplary embodiment of the present disclosure, the encapsulation layer further comprises:
a first encapsulation flat layer, covering the light absorbing layer and being made of transparent material, wherein the reflective layer is provided on a surface of the first encapsulation flat layer away from the driving backplane.

In an exemplary embodiment of the present disclosure, the encapsulation layer further comprises:
a plurality of filling portions, filled in the second light transmitting holes in one-to-one correspondence and being made of transparent material, wherein a surface of each of the filling portions away from the driving backplane and a surface of the light absorbing layer away from the driving backplane are located in the same plane.

In an exemplary embodiment of the present disclosure, the encapsulation layer further comprises:
a plurality of filter portions, filled in the second light transmitting holes, one of the filter portions overlapping with one of the light emitting devices, at least two different filter portions having different colors, and the first encapsulation flat layer covering the filter portions and the light absorbing layer.

In an exemplary embodiment of the present disclosure, the encapsulation layer further comprises:
an organic layer, covering the reflective layer, wherein the second inorganic layer covers the organic layer.

In an exemplary embodiment of the present disclosure, the encapsulation layer further comprises:
a plurality of filter portions, distributed in an array on a side of the reflective layer away from the driving backplane, one of the filter portions overlapping with one of the light emitting devices, and at least two different filter portions have different colors.

In an exemplary embodiment of the present disclosure, the encapsulation layer further comprises:
a second encapsulation flat layer, covering the reflective layer, the filter portions being provided on a surface of the second encapsulation flat layer away from the driving backplane.

In an exemplary embodiment of the present disclosure, the encapsulation layer further comprises:
an organic layer, covering each of the filter portions, wherein the second inorganic layer covers the organic layer.

In an exemplary embodiment of the present disclosure, a number of the first light transmitting holes is the same as a number of the light emitting devices, and the first light transmitting holes overlap with the light emitting devices in one-to-one correspondence.

In an exemplary embodiment of the present disclosure, a number of the first light transmitting holes is less than a number of the light emitting devices, and orthographic projections of at least two of the light emitting devices on the driving backplane are located within an orthographic projection of one same first light transmitting hole on the driving backplane.

In an exemplary embodiment of the present disclosure, a material of the reflective layer comprises at least one of aluminum, silver and molybdenum.

In an exemplary embodiment of the present disclosure, the display panel further comprises:
a cover plate, attached to a surface of the encapsulation layer away from the driving backplane.

According to one aspect of the present disclosure, a display device is provided, comprising any one of the display panels described above.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for those skilled in the art, other accompanying drawings may be obtained based on these accompanying drawings without creative work.

FIG. 1 is a top view of an embodiment of a display panel of the present disclosure.

FIG. 2 is a partial cross-sectional schematic diagram of a first embodiment of the display panel of the present disclosure.

FIG. 3 is a partial cross-sectional schematic diagram of a second embodiment of the display panel of the present disclosure.

FIG. 4 is a partial cross-sectional schematic diagram of a third embodiment of the display panel of the present disclosure.

FIG. 5 is a partial cross-sectional schematic diagram of a fourth embodiment of the display panel of the present disclosure.

FIG. 6 is a partial cross-sectional schematic diagram of a fifth embodiment of the display panel of the present disclosure.

FIG. 7 is a partial cross-sectional schematic diagram of a sixth embodiment of the display panel of the present disclosure.

FIG. 8 is a partial cross-sectional schematic diagram of a seventh embodiment of the display panel of the present disclosure.

### DETAILED DESCRIPTION

Example embodiments will now be described more fully with reference to the accompanying drawings. However, the example embodiments may be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

The terms “a”, “an”, “the”, “said” and “at least one” are used to indicate the presence of one or more elements/components/etc. ; the terms “including” and “having” are used to express an open-ended inclusive meaning and mean that additional elements/components/etc. may exist in addition to the listed elements/components/etc. ; the terms “first”, “second” and “third” etc. are used merely as references and are not intended to limit the quantity of their objects.

In this context, the “overlap” of feature A and feature B means that orthographic projections of feature A and feature B on a plane parallel to a driving backplane at least partially coincide.

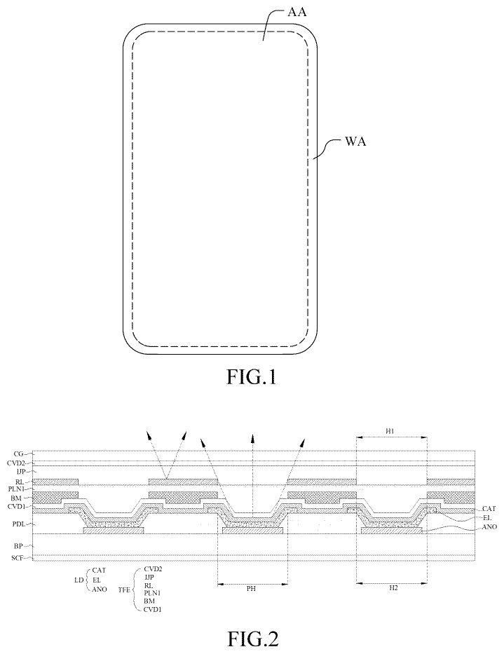

The embodiment of the present disclosure provides a display panel having a mirror display function, that is, it may form an image through reflection so as to observe the environment, and at the same time, it may also display an image through its own light emission. As shown in FIGS. 2 to 8, the display panel may include a driving backplane BP, a plurality of light emitting devices LD and an encapsulation layer TFE, wherein:

The light emitting devices LD are distributed in an array on a side of the driving backplane BP.

The encapsulation layer TFE covers the light emitting devices LD. The encapsulation layer TFE includes a first inorganic layer CVD1, a reflective layer RL and a second inorganic layer CVD2 distributed in sequence in a direction away from the driving backplane BP. The reflective layer RL includes a plurality of first light transmission holes H1, and the first light transmission holes H1 overlap with at least one light emitting device LD.

In the display panel of the embodiment of the present disclosure, since the encapsulation layer TFE has the reflective layer RL, the reflective layer RL may reflect ambient light, so that the display panel has a mirror effect through the encapsulation layer TFE. At the same time, since the brightness of light of different colors decays to different degrees as the viewing angle increases, the displayed image will have color deviation as the viewing angle increases. If the encapsulation layer TFE directly covers the light emitting device LD, it is beneficial to reduce the distance between the reflective layer RL and the light emitting device LD as much as possible while ensuring the encapsulation effect. The smaller the distance between the first light transmitting hole H1 and the light emitting device LD, the larger the emission angle of the light emitted by the light emitting device LD when it is emitted from the first light transmitting hole H1, which is beneficial to increase the light intensity in a larger range, so that color deviation is not easy to occur within a larger viewing angle, thereby improving color deviation.

The following is a detailed description of the display panel of the present disclosure:

As shown in FIG. 1, the display panel may include a display area AA and a peripheral area WA outside the display area AA. The peripheral area WA may be a continuous annular area surrounding the display area AA, or may be a U-shaped area or other shaped area. The display area AA may be used to emit light to display images.

The driving backplane BP has a driving circuit for driving the light emitting device LD to emit light. The driving circuit may include a pixel circuit located in the display area AA and a peripheral circuit located in the peripheral area WA, wherein:

There are multiple pixel circuits, which are arrayed in row and column directions. One pixel circuit may be connected to one light emitting device LD. Of course, there may also be a situation where one pixel circuit is connected to multiple light emitting devices LD. This disclosure only takes the one-to-one connection between pixel circuits and light emitting devices LD as an example for explanation.

The pixel circuit may include multiple transistors and capacitors, which may be 3T1C, 7T1C, 8T1C and other pixel circuits. nTmC means that a pixel circuit includes n transistors (indicated by the letter “T”) and m capacitors (indicated by the letter “C”).

The peripheral circuit may be connected to the pixel circuit and the light emitting device LD, and may control the current passing through the light emitting device LD by the pixel circuit, thereby controlling the brightness of the light emitting device LD. The peripheral circuit may include a gate drive circuit and a light emitting control circuit, etc. Of course, it may also include other circuits, and the specific structure of the peripheral circuit is not particularly limited here.

In some embodiments of the present disclosure, taking the case where the channels of the transistors of the pixel circuit are located in the same semiconductor layer, the driving backplane BP may include a substrate and a semiconductor layer, a first gate insulating layer, a first gate layer, a second gate insulating layer, a second gate layer, an interlayer dielectric layer, a first source-drain layer, a first flat layer, a second source-drain layer, and a second flat layer, which are sequentially arranged in a direction away from the substrate, wherein:

The substrate may be a base of the driving backplane BP, may carry a pixel circuit and a peripheral circuit. The substrate may be a hard or flexible structure. The substrate may be a single-layer or multi-layer structure, and is not specifically limited here.

The semiconductor layer may be disposed on a side of the substrate and include channels of transistors in the pixel circuit, and its material may be a semiconductor material such as polysilicon. The first gate insulating layer may cover the semiconductor layer. The material of the first gate insulating layer may be an insulating material such as silicon nitride or silicon oxide. The first gate layer may be disposed on a surface of the first gate insulating layer away from the substrate, and include a gate of each transistor and a first plate of the capacitor. The second gate insulating layer may cover the first gate layer, and its material may be an insulating material such as silicon nitride or silicon oxide. The second gate layer may be disposed on a surface of the second gate insulating layer away from the substrate, and include a second plate of the capacitor. The second plate overlaps with the first plate to form a capacitor. The interlayer dielectric layer may cover the second gate layer, and its material may include an inorganic insulating material such as silicon nitride or silicon oxide, or an organic insulating material such as an insulating resin.

The first source-drain layer may be disposed on a surface of the interlayer dielectric layer away from the substrate, and may be a single-layer or a multi-layer structure, and its material may include one or more metals such as Ti, Al, Mg, and Ag. The first flat layer may be disposed on a side of the first source-drain layer away from the substrate, and its material may be an insulating material such as resin. For example, a passivation layer of an insulating material such as silicon nitride may be used to cover the first source-drain layer, and then the passivation layer may be covered by the first flat layer.

The second source-drain layer may be disposed on the surface of the first flat layer away from the substrate, and may be a single-layer or a multi-layer structure, and its material may include one or more metals such as Ti, Al, Mg, and Ag. The second flat layer may cover the second source-drain layer, and its material may be an insulating material such as resin.

As shown in FIGS. 2 to 8, each light emitting device LD may be disposed on a side of the driving backplane BP, for example, the light emitting device LD may be disposed on a surface of the second flat layer away from the substrate. The light emitting device LD is located in the display area AA, so that the entire display area AA may emit light. The light emitting device LD may be an organic light emitting diode (OLED), of course, it may also be a Micro LED (micrometer light emitting diode) and a Mini LED (sub-millimeter light emitting diode), or it may be a light emitting device such as a QLED (quantum dot diode).

As shown in FIGS. 2 to 8, in some embodiments of the present disclosure, the light emitting device LD may include a first electrode ANO, a light emitting layer EL, and a second electrode CAT stacked in the direction away from the driving backplane BP, wherein:

The first electrode ANO may be disposed on a side of the driving backplane BP and distributed in an array. For example, the first electrode ANO may be disposed on the surface of the second flat layer away from the substrate. The light emitting layer EL may include at least a hole injection layer, a hole transport layer, a light emitting material layer, an electron transport layer, and an electron injection layer stacked in a direction away from the driving backplane BP. The light emitting devices LD may share the second electrode CAT, that is, the second electrode CAT may be a continuous whole layer structure, and the second electrode CAT may extend to the peripheral area WA. Each light emitting device LD may emit light independently.

As shown in FIGS. 2 to 8, in order to limit light emitting range of the light emitting devices LD and prevent crosstalk, a pixel definition layer PDL may be provided on a surface where the first electrode ANO is provided, and the pixel definition layer PDL may be provided with an opening PH exposing each first electrode ANO. The light emitting layer EL is stacked with the first electrode ANO in the opening PH, so that light emitting device LD may be separated by the pixel definition layer PDL. For example: the pixel definition layer PDL and the first electrode ANO are both provided on the surface of the second flat layer away from the substrate, and the opening PH of the pixel definition layer PDL exposes the first electrode ANO in one-to-one correspondence. At the same time, the opening PH of the pixel definition layer PDL may be smaller than the first electrode ANO exposed therein. A boundary of the opening PH may serve as a boundary of the light emitting device LD.

In some embodiments of the present disclosure, as shown in FIGS. 2 to 4 and 8, each light emitting device LD may directly emit monochromatic light, and different light emitting devices LD may emit different colors of light. For example, light emitting devices LD may be divided into three types with different light emitting colors, and the three colors may be red, green, and blue. There are multiple light emitting devices LD of the same type, and the light emitting colors are the same.

For example, the light emitting layer EL may include a plurality of functional units distributed in an array, and at least some areas of each functional unit is located in an opening PH and in contact with the first electrode ANO. This allows different light emitting devices LD to emit light of different colors. Alternatively, the light emitting material layer of the light emitting layer EL may include material units distributed in an array, and at least some areas of each material unit are located in an opening PH, while the hole injection layer, the hole transport layer, the electron transport layer and the electron injection layer may adopt a whole layer structure. By making different material units use different materials, different light emitting devices LD may also emit different light.

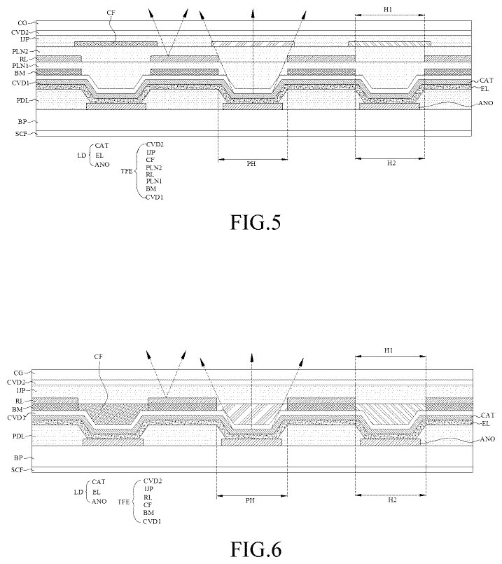

In some embodiments of the present disclosure, as shown in FIGS. 5 to 7, the light emitting colors of the light emitting devices LD may be the same. For example, the light emitting layer EL may also be a whole layer structure, which, in addition to being stacked with the first electrode ANO in the opening PH, also covers the pixel definition layer PDL, so that light emitting devices LD may share the light emitting layer EL. For example, all of the light emitting devices LD may emit white light. Further, each light emitting device LD may include at least three light emitting material layers, each of which may emit monochromatic light and include light emitting material layers that emit red light, green light, and blue light. When all light emitting material layers emits light at the same time, the light emitting device LD may emit white light.

As shown in FIGS. 2 to 8, the encapsulation layer TFE is used to protect the light emitting device LD, which may include a first inorganic layer CVD1, a reflective layer RL and a second inorganic layer CVD2, wherein:

The first inorganic layer CVD1 may cover each light emitting device LD, that is, the first inorganic layer CVD1 may cover a surface of the second electrode CAT away from the driving backplane BP. The material of the first inorganic layer CVD1 may be silicon oxynitride. Of course, the material of the first inorganic layer CVD1 may also be silicon nitride, silicon oxide, and other inorganic insulating materials, and may be formed by plasma enhanced chemical vapor deposition process, and the specific process will not be described in detail here.

The reflective layer RL may be made of a reflective material, such as aluminum, silver, molybdenum or other metals. Of course, it may also be an alloy or non-metallic material as long as it may reflect light. The reflective layer RL may be disposed on a side of the first inorganic layer CVD1 away from the driving backplane BP, and may be provided with a plurality of first light transmitting holes H1, and one first light transmitting hole H1 may overlap with at least one light emitting device LD, so that the light emitted by the light emitting device LD may pass through the light transmitting hole H1 without being completely blocked by the reflective layer RL.

In some embodiments of the present disclosure, as shown in FIGS. 2 to 8, the number of the first light transmitting holes H1 may be the same as the number of the light emitting devices LD, and they may be overlapped in one-to-one correspondence, that is, the openings PH may be overlapped in one-to-one correspondence with the first light transmitting holes H1. Each light emitting device LD may emit light through the first light transmitting hole H1 that overlaps with it. At the same time, in order to prevent the reflective layer RL from blocking the light emitting devices LD, an orthographic projection of each light emitting device LD on the driving backplane BP may be located within an orthographic projection of the first light transmitting hole H1 that overlaps with it on the driving backplane BP, that is, an orthographic projection of the reflective layer RL on the driving backplane BP is located within an orthographic projection of the pixel definition layer PDL on the driving backplane BP. For example, the orthographic projections of the opening PH and the first light transmitting hole H1 may overlap to prevent an area of the reflective layer RL from being too small and reducing the effect of reflecting ambient light.

A shape of the first light transmitting hole H1 may be the same as a shape of the opening PH overlapping with it. Both may be polygons such as rectangle, rhombus, pentagon, hexagon, etc., or ellipse, etc., which are not particularly limited here.

In other embodiments of the present disclosure, the number of first light transmitting holes H1 may be less than the number of light emitting devices LD, and each first light transmitting hole H1 may be larger than each opening PH, that is, larger than the range of each light emitting device LD. The orthographic projections of at least two light emitting devices LD on the driving backplane BP are located within the orthographic projection of the same first light transmitting hole H1 on the driving backplane BP, and the orthographic projection of the reflective layer RL on the driving backplane BP may also be located within the orthographic projection of the pixel definition layer PDL on the driving backplane BP. Light emitted by multiple light emitting devices LD may be emitted from one first light transmitting hole H1.

In other embodiments of the present disclosure, the number of the first light transmitting holes H1 may be less than the number of the light emitting devices LD, but the first light transmitting holes H1 may be overlapped with some of the light emitting devices LD in a one-to-one correspondence, so that the display panel may realize the mirror and display functions only in a part of the display area AA, while other areas may only realize the display function.

The reflective layer RL of the present disclosure may reflect ambient light, thereby achieving a mirror effect. At the same time, due to the existence of the first light transmitting holes H1, the display panel may emit light normally, thereby displaying image.

The second inorganic layer CVD2 may be arranged on a side of the reflective layer RL away from the driving backplane BP to protect the light emitting device LD. The material of the second inorganic layer CVD2 may include an inorganic insulating material such as silicon nitride, silicon oxide, and silicon oxynitride, and may be formed by a plasma enhanced chemical vapor deposition process. The specific process is not described in detail here. The material of the second inorganic layer CVD2 may be different from or the same as that of the first inorganic layer CVD1. For example, in some embodiments of the present disclosure, the first inorganic layer CVD1 may be made of silicon oxynitride, and the second inorganic layer CVD2 may be made of silicon nitride.

The encapsulation layer TFE will be further described in the following by taking the example that each light emitting device LD may directly emit monochromatic light:

As shown in FIGS. 2 to 4, in some embodiments of the present disclosure, the encapsulation layer TFE may further include an organic layer IJP, which may cover the reflective layer RL, and a boundary of the organic layer IJP may be limited to an inner side of a boundary of the first inorganic layer CVD1 by a blocking dam located in the peripheral area WA, and the material of the organic layer IJP may be an organic material such as resin. The organic layer IJP having fluidity (during the manufacturing process) enables planarization. The second inorganic layer CVD2 may cover the organic layer IJP and the first inorganic layer CVD1 not covered by the organic layer IJP, so that intrusion of water and oxygen may be blocked by the second inorganic layer CVD2.

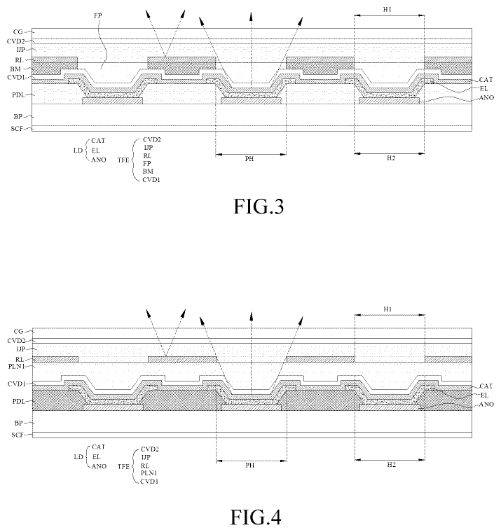

In some embodiments of the present disclosure, as shown in FIGS. 2 and 3, the encapsulation layer TFE further includes a light absorbing layer BM, which may be disposed between the first inorganic layer CVD1 and the reflective layer RL, and may be made of black resin or other light absorbing materials. At the same time, the light absorbing layer BM has a plurality of second light transmitting holes H2, and the second light transmitting holes H2 may overlap with the first light transmitting holes H1 in a one-to-one correspondence, and correspondingly, the second light transmitting holes H2 also overlap with the light emitting devices LD, so that the light absorbing layer BM will not completely block any first light transmitting hole H1, ensuring that light emitted by the light emitting devices LD may pass through the second light transmitting holes H2 and the first light transmitting holes H1 in sequence.

A shape of each of the second light transmitting holes H2 may be the same as a shape of the opening PH overlapping with it. Both may be polygons such as rectangles, rhombuses, pentagons, hexagons, or ellipses, etc., and are not particularly limited here.

Furthermore, in order to prevent the light absorbing layer BM from blocking the light emitting devices LD, an orthographic projection of each of the light emitting devices LD on the driving backplane BP may be located within an orthographic projection of the second light transmitting hole H1 overlapping with it on the driving backplane BP, that is, an orthographic projection of the light absorbing layer BM on the driving backplane BP is located within the orthographic projection of the pixel definition layer PDL on the driving backplane BP.

Furthermore, the orthographic projection of each of the second light transmitting holes H2 on the driving backplane BP is located within the orthographic projection of the first light transmitting hole H1 overlapping with it on the driving backplane BP, preventing the second light transmitting hole H2 from being too large and limiting a range of light received by the first light transmitting hole H1.

Since the first electrode ANO and other film layers on a side of the reflective layer RL close to the substrate may also reflect light, and the patterns of the first electrode ANO and other film layers are relatively complex, there are large differences in the degree of reflection of light. After the light reflected by the reflective layer RL is mixed, it will cause a blurred mirror effect. The above-mentioned light absorption layer BM may absorb at least part of the light reflected by the first electrode ANO and other film layers to avoid blurred mirror effects.

In order to facilitate the setting of the reflective layer RL on a side of the light absorbing layer BM away from the driving backplane BP, as shown in FIG. 2, in some embodiments of the present disclosure, the encapsulation layer TFE may also include a first encapsulation flat layer PLN1. The first encapsulation flat layer PLN1 may cover the light absorbing layer BM and fill the second light transmitting holes H2, and a surface of the first encapsulation flat layer PLN1 away from the driving backplane BP may be a plane. The reflective layer RL may be arranged on the surface of the first encapsulation flat layer PLN1 away from the driving backplane BP, thereby avoiding directly setting the reflective layer RL on an uneven surface such as the light absorbing layer BM or the first inorganic layer CVD1, and preventing occurrence of problems such as fracture when metal and other materials are formed on an uneven surface, thereby ensuring continuity of the reflective layer RL, and at the same time, preventing the reflective layer RL from being uneven and causing it to be unable to reflect light uniformly, thereby ensuring uniformity of the mirror effect.

The first encapsulation flat layer PLN1 is made of a transparent material, and its material may be the same as that of the first flat layer and the second flat layer mentioned above. Of course, the material of the first encapsulation flat layer PLN1 may be the different from the material of the first flat layer and the second flat layer mentioned above, as long as it may achieve planarization. For example, the first encapsulation flat layer PLN1 may be formed by a light transmitting photoresist which is sequentially through processes such as coating, exposure, and development.

In other embodiments of the present disclosure, the first encapsulation flat layer PLN1 mentioned above may not be used to achieve planarization. As shown in FIG. 3, the encapsulation layer TFE may also include a plurality of filling portions FP, which may be filled in the second light transmitting holes H2 in one-to-one correspondence. The filling portions FP are made of a transparent material to ensure that light emitted by the light emitting devices LD may pass through. At the same time, a surface of each of the filling portions FP away from the driving backplane BP and a surface of the light absorbing layer BM away from the driving backplane BP may be located in the same plane. For example, a transparent filling material may be used to cover the light absorbing layer BM and fill the second light transmitting holes H2, and then the filling material may be thinned by grinding or other processes until the light absorbing layer BM is exposed, thereby achieving planarization.

The reflective layer RL may be directly disposed on the surface of the light absorbing layer BM away from the driving backplane BP. If each of the second light transmitting holes H2 is larger than the first light transmitting hole H1 overlapping with it, the reflective layer RL may partially extend to a surface of the filling portion FP away from the driving backplane BP.

It should be noted that the above-mentioned plane is not limited to a geometrically absolute plane. Affected by factors such as process errors, the plane may have certain fluctuations.

In some embodiments of the present disclosure, as shown in FIG. 4, the above-mentioned light absorbing layer BM may not be used, and the first encapsulation flat layer PLN1 may directly cover the first inorganic layer CVD1 to achieve planarization. The reflective layer RL may be disposed on the surface of the first encapsulation flat layer PLN1 away from the driving backplane BP. At the same time, the pixel definition layer PDL may be made of a light absorbing material such as a black resin, thereby playing a similar role to the light absorbing layer BM and absorbing light emitted by the light emitting devices LD.

The encapsulation layer TFE will be further described in the following by taking the case where the light emitting colors of the light emitting devices LD are the same as an example:

In order to realize color display of the display panel, as shown in FIGS. 5 to 8, the encapsulation layer TFE may include a plurality of filter portions CF. Each filter portion CF may only transmit monochromatic light, and different filter portions CF have different colors. A filter portion CF may be arranged with a light emitting device LD in a direction perpendicular to the driving backplane BP, and overlap with the light emitting device LD. An orthographic projection of the filter portion CF on the driving backplane BP and an orthographic projection of the reflective layer RL on the driving backplane BP overlap partially at most. White light emitted by the light emitting device LD becomes monochromatic light after passing through the filter portion CF, so that color display may be realized by the light emitting device LD cooperating with the filter portion CF. Moreover, by integrating the filter portion CF into the encapsulation layer TFE, a distance between the filter portion CF and the light emitting device LD may be minimized as much as possible, reducing limitation of the light output angle of the filter portion CF.

In some embodiments of the present disclosure, as shown in FIG. 6, the filter portions CF may be filled in the second light transmitting holes H2 of the light absorbing layer BM and overlap with the light emitting devices LD in one-to-one correspondence. The first encapsulation flat layer PLN1 may cover the filter portion CF in addition to covering the light absorbing layer BM.

In some embodiments of the present disclosure, as shown in FIG. 5, the filter portions CF is distributed in an array on the side of the reflective layer RL away from the driving backplane BP. For example, the encapsulation layer TFE may further include a second encapsulation flat layer PLN2, which may cover the reflective layer RL. The material of the second encapsulation flat layer PLN2 may be the same as that of the first encapsulation flat layer PLN1. The filter portion CF may be disposed on a surface of the second encapsulation flat layer PLN2 away from the driving backplane BP. The organic layer IJP may cover the filter portion CF.

In some embodiments of the present disclosure, as shown in FIG. 8, in the case where each light emitting device LD may directly emit monochromatic light, the above-mentioned filter portion CF may also be used. In this case, the filter portion CF may be used to reduce the ambient light that passes through the reflective layer RL and irradiates a reflective film such as the first electrode ANO, thereby reducing reflection of the ambient light by a film layer such as the first electrode ANO other than the reflective layer RL, which is beneficial to improving the mirror effect.

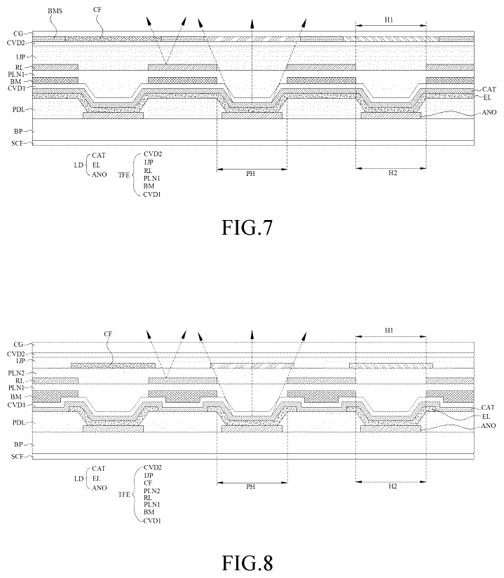

In some embodiments of the present disclosure, as shown in FIG. 7, the above-mentioned filter portion CF and a partition part BMS may also be arranged as a whole on a side of the encapsulation layer TFE away from the driving backplane BP, for example, on a surface of the second inorganic layer CVD2 away from the driving backplane BP.

In some embodiments of the present disclosure, the display panel may further include a cover plate CG, which may be made of a transparent material such as glass and acrylic. As shown in FIGS. 2 to 6 and 8, if the encapsulation layer TFE includes the filter portion CF, the cover plate CG may be attached to the surface of the encapsulation layer TFE away from the driving backplane BP directly or through an adhesive, for example, attached to the surface of the second inorganic layer CVD2 away from the driving backplane BP. As shown in FIG. 7, if the filter portion CF is located on the side of the encapsulation layer TFE away from the driving backplane BP, the cover plate CG may be attached to the surface of the filter portion CF away from the driving backplane BP directly or through an adhesive. At the same time, the filter portion CF may be separated by the partition portion BMS arranged on the same layer, and the partition portion BMS is a light transmitting structure.

It should be noted that, as shown in FIGS. 5, 7 and 8, a range of the filter portion CF may be larger than that of the light emitting device LD overlapped therewith, that is, a boundary of the orthographic projection of the first light transmitting hole H1 on the driving backplane BP is located on an inner side of a boundary of the orthographic projection of the filter portion CF overlapped therewith on the driving backplane BP, so that all light emitted from the first light transmitting hole H1 may pass through the filter portion CF and will not be emitted without passing through the filter portion CF.

In addition, in some embodiments of the present disclosure, as shown in FIGS. 2 to 8, the display panel may further include a protective layer SCF, which may be provided on a side of the driving backplane BP away from the light emitting device LD. For example, the protective layer SCF may be provided on a surface of the substrate away from the light emitting device LD. The protective layer may include an adhesive layer, a buffer layer and a heat dissipation layer, wherein the buffer layer may be bonded to the surface of the substrate away from the light emitting device LD through the adhesive layer, and the heat dissipation layer may be provided on a surface of the buffer layer away from the substrate. The adhesive layer may be made of a material having an adhesive function such as grid glue. The buffer layer may be made of a flexible material such as foam. The heat dissipation layer may be made of copper or other metal or non-metal materials with good thermal conductivity. In addition, a back film may be attached to the surface of the substrate away from the light emitting device LD, and the buffer layer may be bonded to a surface of the back film away from the substrate through the adhesive layer. A supporting layer of a material such as stainless steel may also be provided on a side of the heat dissipation layer away from the driving backplane.

The present disclosure also provides a display device, which may include a display panel of any of the above embodiments. The specific structure and beneficial effects may be referred to the embodiments of the display panel above, and will not be described in detail here. The display device of the present disclosure may be used for a rearview mirror, a makeup mirror, or an advertising display, and its application scenario is not particularly limited here.

Those skilled in the art will readily appreciate other embodiments of the present disclosure after considering the specification and practicing the disclosure disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising:
a driving backplane;
a plurality of light emitting devices, distributed in an array on a side of the driving backplane;
an encapsulation layer, covering the light emitting devices, wherein the encapsulation layer comprises a first inorganic layer, a reflective layer and a second inorganic layer distributed in sequence in a direction away from the driving backplane; the reflective layer comprises a plurality of first light transmitting holes, and the first light transmitting holes overlap with at least one of the light emitting devices.

2. The display panel according to claim 1, wherein the encapsulation layer further comprises:
a light absorbing layer, disposed between the first inorganic layer and the reflective layer; the light absorbing layer having a plurality of second light transmitting holes, and one of the second light transmitting holes overlapping with one of the first light transmitting holes.

3. The display panel according to claim 2, wherein the encapsulation layer further comprises:
a first encapsulation flat layer, covering the light absorbing layer and being made of transparent material, wherein the reflective layer is provided on a surface of the first encapsulation flat layer away from the driving backplane.

4. The display panel according to claim 2, wherein the encapsulation layer further comprises:
a plurality of filling portions, filled in the second light transmitting holes in one-to-one correspondence and being made of transparent material, wherein a surface of each of the filling portions away from the driving backplane and a surface of the light absorbing layer away from the driving backplane are located in the same plane.

5. The display panel according to claim 3, wherein the encapsulation layer further comprises:
a plurality of filter portions, filled in the second light transmitting holes, one of the filter portions overlapping with one of the light emitting devices, at least two different filter portions having different colors, and the first encapsulation flat layer covering the filter portions and the light absorbing layer.

6. The display panel according to claim 2, wherein the encapsulation layer further comprises:
an organic layer, covering the reflective layer, wherein the second inorganic layer covers the organic layer.

7. The display panel according to claim 1, wherein the encapsulation layer further comprises:
a plurality of filter portions, distributed in an array on a side of the reflective layer away from the driving backplane, one of the filter portions overlapping with one of the light emitting devices, and at least two different filter portions have different colors.

8. The display panel according to claim 7, wherein the encapsulation layer further comprises:
a second encapsulation flat layer, covering the reflective layer, the filter portions being provided on a surface of the second encapsulation flat layer away from the driving backplane.

9. The display panel according to claim 7, wherein the encapsulation layer further comprises:
an organic layer, covering each of the filter portions, wherein the second inorganic layer covers the organic layer.

10. The display panel according to claim 1, wherein a number of the first light transmitting holes is the same as a number of the light emitting devices, and the first light transmitting holes overlap with the light emitting devices in one-to-one correspondence.

11. The display panel according to claim 1, wherein a number of the first light transmitting holes is less than a number of the light emitting devices, and orthographic projections of at least two of the light emitting devices on the driving backplane are located within an orthographic projection of one same first light transmitting hole on the driving backplane.

12. The display panel according to claim 1, wherein a material of the reflective layer comprises at least one of aluminum, silver and molybdenum.

13. The display panel according to claim 1, further comprising:
a cover plate, attached to a surface of the encapsulation layer away from the driving backplane.

14. A display device comprising the display panel according to claim 1.

15. A display device comprising the display panel according to claim 2.

16. A display device comprising the display panel according to claim 3.

17. A display device comprising the display panel according to claim 4.

18. A display device comprising the display panel according to claim 5.

19. A display device comprising the display panel according to claim 6.

20. A display device comprising the display panel according to claim 7.
